(19) United States
(12) Patent Application Publication
(10) Pub. No.: US 2024/0162077 A1
(43) Pub. Date: May 16, 2024

(54) SYSTEMS AND APPARATUS FOR SEMICONDUCTOR EQUIPMENT

(71) Applicant: ASM IP Holding B.V., Almere (NL)

(72) Inventors: Rajmohan Muthaiah, Phoenix, AZ (US); Shubham Garg, Tempe, AZ (US); Todd Dunn, Cave Creek, AZ (US); Hong Gao, San Jose, CA (US); Joaquin Aguilar Santillan, Gilbert, AZ (US); Arjav Prafulkumar Vashi, Tempe, AZ (US)

(21) Appl. No.: 18/388,661

(22) Filed: Nov. 10, 2023

Related U.S. Application Data
(60) Provisional application No. 63/425,396, filed on Nov. 15, 2022.

(51) Int. Cl. H01L 21/687

(52) U.S. Cl. CPC H01L 21/68785; H01L 21/68742; H01L 21/68757

(57) ABSTRACT

Various embodiments of the present technology may provide an apparatus for use within a reaction chamber. The apparatus includes a susceptor plate having through-holes for which lift pins may be disposed therein. In addition, the susceptor may include an electrostatic chucking function. The susceptor may also include a metal interconnect that is electrically connected to other metal interconnects with a brazing material.

### CROSS-REFERENCE TO RELATED APPLICATIONS

This application is a nonprovisional of, and claims priority to and the benefit of, U.S. Provisional Patent Application No. 63/425,396, filed Nov. 15, 2022 and entitled “SYSTEMS AND APPARATUS FOR SEMICONDUCTOR EQUIPMENT,” which is hereby incorporated by reference herein.

### FIELD OF INVENTION

The present disclosure generally relates to an apparatus for semiconductor equipment. More particularly, the present disclosure relates to materials used to form a susceptor, a lift pin, and a brazing material.

### BACKGROUND OF THE TECHNOLOGY

Equipment used during the semiconductor manufacturing process may provide a susceptor having an electrostatic chucking function. Conventional ceramic susceptors suffer from lowered bulk resistivity at high temperatures (e.g., >550° C.) and therefore the chucking function is reduced or ineffective. In addition, conventional ceramic susceptors may exhibit low thermal conductivity (e.g., 35-40 W/mK) at high temperatures, which may cause thermal non-uniformity in a wafer.

In addition, conventional metal susceptors may provide better thermal uniformity than ceramic susceptors, however, metal susceptors are temperature limited (to about 450° C.). In addition, conventional ceramic-coated (e.g., pure AIN) metal susceptors may exhibit low thermal conductivity and loss of volume resistivity at high temperatures (e.g., >550° C.), which may result in ESC drifting and non-uniformity in the wafer.

Semiconductor manufacturing equipment may also include lift pins. Conventional lift pins are formed from a ceramic (e.g., AlN, SiC, and A1203), however, ceramic lift pins may suffer from cracking and breaking due to the low fracture toughness of the ceramic material (e.g., 3-5 MPa·m^{1/2}) and/or low flexural strength.

The susceptor may also include various metal interconnects that are connected to each other with a brazing material. Conventional brazing material may suffer from oxidation when the susceptor is operated at high temperatures (e.g., ˜650-700° C.). Oxidation may weaken the brazed joints, which may lead to poor electrical connections and loss of electrostatic chucking function. In addition, conventional metal interconnects formed from pure molybdenum may lose some structural stability at high temperatures (e.g., 2000° C.) due to the brittle nature of the pure molybdenum.

### SUMMARY OF THE INVENTION

Various embodiments of the present technology may provide an apparatus for use within a reaction chamber. The apparatus includes a susceptor plate having through-holes for which lift pins may be disposed therein. In addition, the susceptor may include an electrostatic chucking function. The susceptor may also include a metal interconnect that is electrically connected to other metal interconnects with a brazing material.

According to one aspect, an apparatus comprises a susceptor comprising a first surface and a second surface, and a plurality of through-holes extending from the first surface to the second surface, wherein the susceptor comprises a metal alloy and a coating overlying the metal alloy; and a plurality of lift pins, wherein each lift pin is disposed within a respective through-hole from the plurality of through-holes.

In one embodiment of the above apparatus, the coating comprises wurtzite boron nitride.

In one embodiment of the above apparatus, the coating comprises wurtzite boron nitride doped with titanium dioxide.

In one embodiment of the above apparatus, the coating comprises aluminum nitride doped with titanium dioxide, wherein the titanium dioxide is 0.1 to 3 atomic %.

In one embodiment of the above apparatus, the coating comprises aluminum oxide doped with titanium dioxide, wherein the titanium dioxide is 0.1 to 3 atomic %.

In one embodiment of the above apparatus, each lift pin is formed from an alloy comprising aluminum oxide and zirconium.

In one embodiment of the above apparatus, each lift pin comprises aluminum oxide and a coating overlying the aluminum oxide, wherein the coating comprises yttria-stabilized zirconia.

In one embodiment of the above apparatus, each lift pin is formed from an alloy of aluminum oxide and silicon nitride.

According to another aspect, an apparatus comprises a susceptor comprising a first surface and a second surface, and a plurality of through-holes extending from the first surface to the second surface, wherein the susceptor comprises a first ceramic material comprising one of aluminum nitride, silicon carbide, or aluminum oxide; and a plurality of lift pins, wherein each lift pin is disposed within a respective through-hole from the plurality of through-holes, and wherein each lift pin comprises a second ceramic material.

In one embodiment of the above apparatus, the first ceramic material is doped with a dopant comprising one of silicon nitride, magnesium oxide, or beryllium oxide.

In one embodiment of the above apparatus, the first ceramic material comprises an alloy of aluminum nitride and wurtzite boron nitride.

In one embodiment of the above apparatus, the alloy further comprises titanium dioxide.

In one embodiment of the above apparatus, each lift pin is formed from an alloy comprising aluminum oxide and zirconium.

In one embodiment of the above apparatus, each lift pin comprises aluminum oxide and a coating overlying the aluminum oxide, wherein the coating comprises yttria-stabilized zirconia.

In one embodiment of the above apparatus, each lift pin is formed from an alloy of aluminum oxide and silicon nitride.

In one embodiment of the above apparatus, the susceptor comprises a heating element embedded within the susceptor and a plurality of electrodes embedded within the susceptor and configured to generate an electric charge at the first surface of the susceptor.

According to yet another aspect, a susceptor comprises a plate comprising: a first surface and a second surface; a plurality of through-holes extending from the first surface to the second surface; and a first metal interconnect disposed at the second surface; and a shaft connected to the second surface of the heater and comprising: a second metal interconnect disposed adjacent to the first metal interconnect, wherein the second metal interconnect is electrically connected to the first metal interconnect with a metal brazing material; and a metal rod disposed adjacent to the second metal interconnect, wherein the metal rod is electrically connected to the second metal interconnect with the metal brazing material.

In one embodiment of the above susceptor, the metal brazing material is an alloy comprising at least five metals selected from the group consisting of: aluminum, chromium, molybdenum, titanium, tantalum, gold, lead, and platinum.

In one embodiment of the above susceptor, the first metal interconnect is formed from molybdenum doped with lanthanum oxide, wherein the lanthanum oxide is 0.1 to 0.7 atomic %.

In one embodiment of the above susceptor, the susceptor further comprises: a plurality of electrodes embedded within the heater and electrically connected to the first metal interconnect, wherein the plurality of electrodes are configured to generate an electric charge at the first surface of the heater.

### BRIEF DESCRIPTION OF THE DRAWING FIGURES

A more complete understanding of the present technology may be derived by referring to the detailed description when considered in connection with the following illustrative figures. In the following figures, like reference numbers refer to similar elements and steps throughout the figures.

FIG. 1 representatively illustrates a cross sectional view of a system in accordance with an exemplary embodiment of the present technology;

FIG. 2 representatively illustrates a cross sectional view of a susceptor in accordance with an exemplary embodiment of the present technology; and

FIG. 3 representatively illustrates a cross sectional view of a portion of the susceptor in accordance with an exemplary embodiment of the present technology.

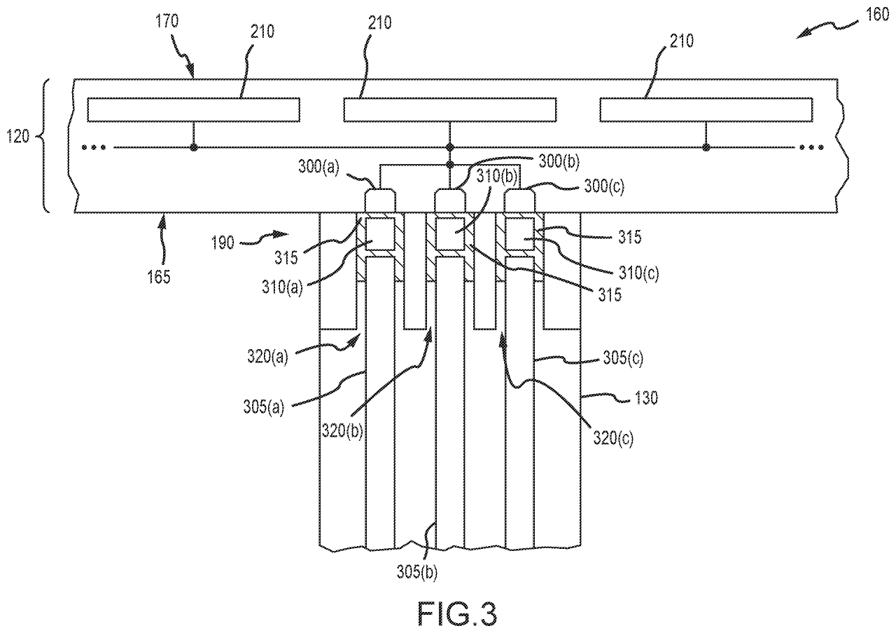

### DETAILED DESCRIPTION OF EXEMPLARY EMBODIMENTS

The present technology may be described in terms of functional block components and various processing steps. Such functional blocks may be realized by any number of components configured to perform the specified functions and achieve the various results. For example, the present technology may employ various showerheads, susceptor types, and lift pin types. Further, the present technology may employ any method for applying various coatings and/or forming a susceptor and lift pin.

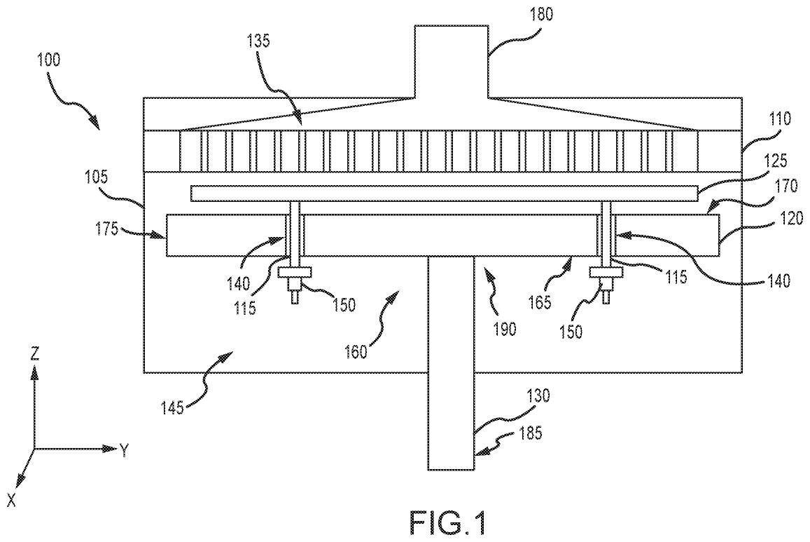

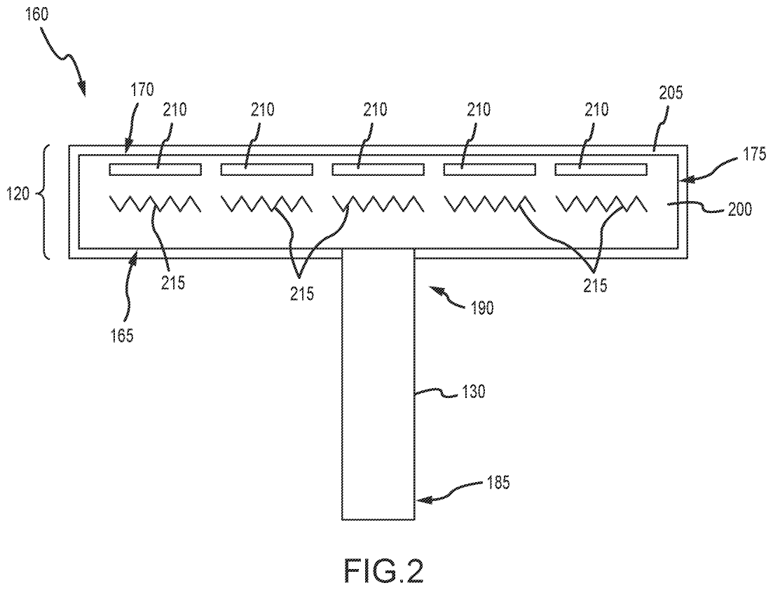

Referring to FIGS. 1 and 2, an exemplary system 100 may comprise a reaction chamber 105 for processing a substrate, such as a wafer 125. The reaction chamber 105 may comprise an interior space 145 defined by a sidewalls, a bottom surface, and a showerhead 110 disposed parallel to the bottom surface and above the wafer 125.

The system 100 may further comprise an inlet 180 to deliver various precursors and/or reactants to the reaction chamber 105 via the showerhead 110.

The showerhead 110 may comprise a plurality of through-holes 135 configured to flow precursor from the inlet 180 toward the wafer 125.

The system 100 may further comprise a susceptor 160 disposed within the interior space 145 of the reaction chamber 105 and configured to support the wafer 125. For example, the susceptor 160 may comprise a plate 120 supported by a shaft 130. The shaft 130 may comprise a first end 190 that is directly connected to the bottom surface 165 and a second end 185, that is opposite the first end 185 and extends outside of the reaction chamber 105. In various embodiments, the susceptor 160 may be configured to move up and down along a z-axis (Z), for example from a first position to a second position.

The plate 120 may comprise a top surface 170 that is horizontally-oriented and positioned directly below the showerhead 110. The wafer 125 (or other substrate) may rest on the top surface 170 of the plate 120 during processing. The plate 120 may further comprise a bottom surface 165 that is opposite and parallel to the top surface 170. In various embodiments, the plate 120 may comprise a plurality of through-holes 140 that extend from the top surface 170 to the bottom surface 165.

In various embodiments, the susceptor 160 may be configured to heat the wafer 125. For example, the plate 120 may comprise a heating element 215, such as a resistive heating element or other suitable heating system and/or device. In various embodiments, the heating element 215 may be selected to operate at high temperatures, such as in the range of approximately 1000° C. to 2000° C.

In various embodiments, the susceptor 160 may be configured to provide an electrostatic chucking function. For example, the plate 120 may comprise a plurality of electrodes 210 embedded within a bulk portion 200 of the plate 120.

In various embodiments, the bulk portion 200 of the plate 120 may be formed from ceramic material (e.g., alumina, AlOx, AlN, SiC, Al₂O₃), or a metal material (e.g., stainless steel, Hastelloy, or the like).

In one embodiment, the bulk portion 200 of the plate 120 may be formed from a ceramic material (e.g., alumina, AlOx, AlN, SiC, Al₂O₃) having a dopant, such as silicon nitride (SiN), silicon carbide (SiC), beryllium oxide (Be(x)O(y)), boron nitride (BN), or magnesium oxide (MgO). For example, in the case of SiN, the dopant may have a concentration in a range from 0.5 atomic % to 5 atomic %. In the case of SiC, the dopant may have a concentration in a range from 0.5 atomic % to 10 atomic %. In the case of Be(x)O(y), the dopant may have a concentration in a range from 0.1 atomic % to 10 atomic %. In the case of BN, the dopant may have a concentration in a range from 0.1 atomic % to 5 atomic %. In the case of MgO, the dopant may have a concentration in a range from 0.1 atomic % to 5 atomic %. Including a dopant, such as silicon nitride (SiN), silicon carbide (SiC), beryllium oxide (Be(x)O(y)), boron nitride (BN), or magnesium oxide (MgO), in the ceramic material may increase the bulk resistivity of the ceramic material, which can improve the electrostatic chucking capability of the plate 120, particularly when the plate 120 is heated to high temperatures (e.g., >550° C.).

In another embodiment, the bulk portion 200 of the plate 120 may be formed from an alloy comprising aluminum nitride (A1N) and wurtzite boron nitride. In this case, the concentration ratio of aluminum nitride to wurtzite boron nitride may range from 10:1 to 50:1. Aluminum nitride alone can provide desired thermal conductivity (e.g., ˜240 W/mK) and high bulk resistivity (e.g., 1E\hat{ }16). However, at high temperatures (e.g., >550 C), the thermal conductivity of aluminum nitride decreases to 35-40 W/mK, which may result in thermal non-uniformity in the wafer 125. Wurtzite boron nitride is an ultra-high thermally conductive material (˜1000 W/mK at room temperature) and has a high bulk resistivity (e.g., 1E\hat{ }15). In addition, at high temperatures (e.g., >500 C), its thermal conductivity is in the range of —50-60 W/mK. Moreover, the bulk resistivity of wurtzite boron nitride is one order of magnitude higher than aluminum nitride. Therefore, an alloy of aluminum nitride with wurtzite boron nitride improves the thermal performance of the plate 120.

In another embodiment, the bulk portion of the plate 120 may be formed from an alloy comprising titanium dioxide (TiO₂) and wurtzite boron nitride. In this case, the alloy may have a chemical composition of 0.1% to 5% titanium dioxide, and 95% to 99.9% wurtzite boron nitride. In the present case, the plate 120 may exhibit improved thermal conductivity and electrostatic chucking performance compared to conventional materials.

In another embodiment, the bulk portion 200 of the plate 120 may be formed from a metal alloy material, such as Hastelloy C22, or stainless steel. In various embodiments, the plate 120 may further comprise a coating 205 overlying the bulk portion 200. In some embodiments, the coating 205 may overlie both the top and bottom surfaces 170, 165, as well as side surfaces 175. However, in other embodiments, the coating 205 may overlie only the top surface 170. In other embodiments, the coating 205 may overlie only the top surface 170 and the side surface 175.

In one embodiment, the coating 205 may comprise wurtzite boron nitride. In other cases, the coating 205 is limited to wurtzite boron nitride. In the present case, the thickness of the coating 205 may range from 1 μm to 0.1 mm. In various embodiments, a metal plate 120 having a wurtzite boron nitride coating improves the thermal conductivity and bulk resistivity of the plate 120 at high temperatures, such as greater than 500° C.

In another embodiment, the coating 205 may comprise aluminum nitride and titanium dioxide, wherein the composition includes 0.1% to 3% of titanium dioxide. In the present case, the thickness of the coating 205 may range from 1 μm to 0.1 mm. Titanium dioxide has eight orders of magnitude higher volume resistance than aluminum nitride. A metal plate 120 having a coating comprising aluminum nitride and titanium dioxide provides improved volume resistivity and high temperature performance compared to aluminum nitride only coatings. In addition, in some cases, a coating comprising aluminum nitride and titanium dioxide improves electrostatic chucking capabilities of the plate 120 compared to aluminum nitride only coatings.

In another embodiment, the coating 205 may comprise a mixture of Al₂O₃ doped with titanium dioxide, wherein the composition includes 0.1% to 3% of titanium dioxide. In the present case, the thickness of the coating 205 may range from 1 μm to 0.1 mm. Titanium dioxide has six orders of magnitude higher volume resistance than aluminum oxide. Accordingly, a metal plate 120 having a coating comprising aluminum oxide and titanium dioxide provides improved volume resistivity and high temperature performance compared to aluminum oxide only coatings. In addition, in some cases, a coating comprising aluminum oxide and titanium dioxide improves electrostatic chucking capabilities of the plate 120 compared to aluminum oxide only coatings.

In another embodiment, the coating 205 may comprise wurtzite boron nitride doped with titanium dioxide. In this case, the chemical composition may be 95% to 99.9% wurtzite boron nitride and 0.1% to 5% titanium dioxide. In the present case, the thickness of the coating 205 may range from 1 μm to 0.1 mm. A coating 205 of wurtzite boron nitride doped with titanium dioxide may provide improved bulk resistivity and thermal conductivity of the plate 120 compared to conventional coatings.

In various embodiments the coating 205 may be applied using any suitable method or process.

In various embodiments, the plate 120 may further comprise a variety of electrical interconnects, such as a first electrical interconnect 300 disposed at the bottom surface 165. The first electrical interconnect 300 may be formed from a metal, such as molybdenum doped with lanthanum oxide. In an exemplary embodiment, the molybdenum is doped with 0.3% to 0.7% lanthanum oxide. An electrical interconnect formed from molybdenum doped with lanthanum oxide exhibits improved ductility and retains structural stability at temperatures up to 2000° C. compared to pure molybdenum, which can become brittle and crack. The first electrical interconnect 300, therefore, exhibits structural stability at temperatures up to 2000° C. and provides improved electrical conductivity and electrostatic chucking capability.

In various embodiments, the shaft 130 may be configured to provide a conduit to house various electrical interconnects that provide power to the heating element 215 and/or electrodes 210. For example, the shaft 130 may have a hollow center wherein electrical interconnects may be disposed therein. The electrical interconnects may comprise a plurality of electrical rods, such as a first electrical rod 305(a), a second electrical rod 305(b), and a third electrical rod 305(c), are disposed therein. Each electrical rod 305 may extend into a respective cavity 320 within the shaft 130. Each electrical rod 305 may be formed from nickel or any other suitable metal having electrical conductivity.

In various embodiments, the electrical interconnects may further comprise a metal layer 310 disposed within the cavity 320. In various embodiments, the metal layer 310 may comprise an alloy of two or more of iron, nickel, cobalt, titanium, tantalum, and zirconium. The metal layer 310 may be disposed near the interface of where the shaft 130 and the bottom surface 165 of the plate 120 are joined. In various embodiments, the metal layer 310 may have a thickness in the range of 1 μm to 1 mm. In an exemplary embodiment, the electrical rod 305 may be electrically connected to the metal layer 310 with a brazing material 315.

In an exemplary embodiment, the brazing material 315 may comprise a high entropy alloy comprising a mixture of five of more metals selected from aluminum, chromium, molybdenum, titanium, tantalum, gold, lead, and platinum. A high entropy alloy, as disclosed, may provide improved crack resistance and oxidation resistance properties at high temperatures (e.g., ˜650-700° C.), which improves the overall brazed joint reliability and electrical connectivity. In cases where the plate 120 has electrostatic chucking capabilities, the high entropy brazing material 315 may improve the chucking capability due to the improved joint reliability and electrical connectivity.

In various embodiments, the metal layer 310 may be electrically connected to the first electrical interconnect 300 with the brazing material 315.

In various embodiments, the electrical rod 305, metal layer 310, and first metal interconnect 300 are all electrically connected to each other. In addition, the plate 120 may further comprise additional electrical interconnects to connect the first electrical interconnect 300 to the heating element 215 and/or the electrodes 210.

In various embodiments, the system 100 may comprise a plurality of lift pins 140, wherein each lift pin 140 is disposed in a respective through-hole 140. In some embodiments, the lift pin 140 may comprise a weight 150 positioned near the bottom surface 165. In various embodiments, a body of the lift pin 140 may be formed from a material comprising a ceramic material, such a Al₂O₃.

In one embodiment, the body of the lift pin 140 may be formed from an alloy comprising ceramic material (e.g., aluminum oxide, Al₂O₃) and zirconium. The alloy may comprise 0.1 atomic % to 10 atomic % zirconium. Lift pins formed from aluminum oxide alone have a low fracture toughness (e.g., 3-5 MPa·m^{1/2}) compared to other metals, such as zirconium, having a fracture toughness of over 20 MPa·m^{1/2}. Therefore, an alloy comprising aluminum oxide and zirconium can exhibit a 150% to 400% higher fracture toughness than aluminum oxide alone.

In another embodiment, the body of the lift pin 140 may be formed from a ceramic material (e.g., Al₂O₃) and further comprise a coating overlying the ceramic body material. For example, the coating may comprise yttria-stabilized zirconia. The coating may have a thickness in the range of 1 μm to 0.1 mm. In various embodiment, the coating on the lift pin 140 may be applied using any suitable method or process. Lift pins coated with yttria-stabilized zirconia improve the fracture toughness of the ceramic material to prevent crack propagation due to the high fracture toughness of yttria-stabilized zirconia (10 MPa·m^{1/2}).

In another embodiment, the lift pin 140 may be formed from a SiAlON ceramic based on the elements silicon (Si), aluminium (Al), oxygen (O) and nitrogen (N). In some cases, SiAlON may be formed from a mixture of Al₂O₃ and silicon nitride. Lift pins formed from SiAlON exhibit 100% higher flexural strength and fracture toughness than pure Al₂O₃. Therefore, lift pins formed from SiAlON will prevent cracking and extend the lifetime of the lift pin.

In various embodiments, the atomic percentage or composition ratio may be measured using conventional techniques and methods.

In the foregoing description, the technology has been described with reference to specific exemplary embodiments. The particular implementations shown and described are illustrative of the technology and its best mode and are not intended to otherwise limit the scope of the present technology in any way. Indeed, for the sake of brevity, conventional manufacturing, connection, preparation, and other functional aspects of the method and system may not be described in detail. Furthermore, the connecting lines shown in the various figures are intended to represent exemplary functional relationships and/or steps between the various elements. Many alternative or additional functional relationships or physical connections may be present in a practical system.

The technology has been described with reference to specific exemplary embodiments. Various modifications and changes, however, may be made without departing from the scope of the present technology. The description and figures are to be regarded in an illustrative manner, rather than a restrictive one and all such modifications are intended to be included within the scope of the present technology. Accordingly, the scope of the technology should be determined by the generic embodiments described and their legal equivalents rather than by merely the specific examples described above. For example, the steps recited in any method or process embodiment may be executed in any order, unless otherwise expressly specified, and are not limited to the explicit order presented in the specific examples. Additionally, the components and/or elements recited in any apparatus embodiment may be assembled or otherwise operationally configured in a variety of permutations to produce substantially the same result as the present technology and are accordingly not limited to the specific configuration recited in the specific examples.

Benefits, other advantages and solutions to problems have been described above with regard to particular embodiments. Any benefit, advantage, solution to problems or any element that may cause any particular benefit, advantage or solution to occur or to become more pronounced, however, is not to be construed as a critical, required or essential feature or component.

The terms “comprises”, “comprising”, or any variation thereof, are intended to reference a non-exclusive inclusion, such that a process, method, article, composition or apparatus that comprises a list of elements does not include only those elements recited, but may also include other elements not expressly listed or inherent to such process, method, article, composition or apparatus. Other combinations and/or modifications of the above-described structures, arrangements, applications, proportions, elements, materials or components used in the practice of the present technology, in addition to those not specifically recited, may be varied or otherwise particularly adapted to specific environments, manufacturing specifications, design parameters or other operating requirements without departing from the general principles of the same.

The present technology has been described above with reference to an exemplary embodiment. However, changes and modifications may be made to the exemplary embodiment without departing from the scope of the present technology. These and other changes or modifications are intended to be included within the scope of the present technology, as expressed in the following claims.

What is claimed is:

1. An apparatus, comprising:
a susceptor comprising a first surface and a second surface, and a plurality of through-holes extending from the first surface to the second surface, wherein the susceptor comprises a metal alloy and a coating overlying the metal alloy; and
a plurality of lift pins, wherein each lift pin is disposed within a respective through-hole from the plurality of through-holes.

2. The apparatus according to claim 1, wherein the coating comprises wurtzite boron nitride.

3. The apparatus according to claim 1, wherein the coating comprises wurtzite boron nitride doped with titanium dioxide.

4. The apparatus according to claim 1, wherein the coating comprises aluminum nitride doped with titanium dioxide, wherein the titanium dioxide has a concentration of 0.1 to 3 atomic %.

5. The apparatus according to claim 1, wherein the coating comprises aluminum oxide doped with titanium dioxide, wherein the titanium dioxide has a concentration of 0.1 to 3 atomic %.

6. The apparatus according to claim 1, wherein each lift pin is formed from an alloy comprising aluminum oxide and zirconium.

7. The apparatus according to claim 1, wherein each lift pin comprises aluminum oxide and a coating overlying the aluminum oxide, wherein the coating comprises yttria-stabilized zirconia.

8. The apparatus according to claim 1, wherein each lift pin is formed from an alloy of aluminum oxide and silicon nitride.

9. An apparatus, comprising:
a susceptor comprising a first surface and a second surface, and a plurality of through-holes extending from the first surface to the second surface, wherein the susceptor comprises a first ceramic material comprising one of aluminum nitride, silicon carbide, or aluminum oxide; and
a plurality of lift pins, wherein each lift pin is disposed within a respective through-hole from the plurality of through-holes, and wherein each lift pin comprises a second ceramic material.

10. The apparatus according to claim 9, wherein the first ceramic material is doped with a dopant comprising one of silicon nitride, magnesium oxide, or beryllium oxide.

11. The apparatus according to claim 9, wherein the first ceramic material comprises an alloy of aluminum nitride and wurtzite boron nitride.

12. The apparatus according to claim 11, wherein the alloy further comprises titanium dioxide.

13. The apparatus according to claim 9, wherein each lift pin is formed from an alloy comprising aluminum oxide and zirconium.

14. The apparatus according to claim 9, wherein each lift pin comprises aluminum oxide and a coating overlying the aluminum oxide, wherein the coating comprises yttria-stabilized zirconia.

15. The apparatus according to claim 9, wherein each lift pin is formed from an alloy of aluminum oxide and silicon nitride.

16. The apparatus according to claim 9, wherein the susceptor comprises a heating element embedded within the susceptor and a plurality of electrodes embedded within the susceptor and configured to generate an electric charge at the first surface of the susceptor.

17. A susceptor, comprising:
a plate comprising:
a first surface and a second surface;
a plurality of through-holes extending from the first surface to the second surface; and
a first metal interconnect disposed at the second surface; and
a shaft connected to the second surface of the heater and comprising:
a second metal interconnect disposed adjacent to the first metal interconnect, wherein the second metal interconnect is electrically connected to the first metal interconnect with a metal brazing material; and
a metal rod disposed adjacent to the second metal interconnect, wherein the metal rod is electrically connected to the second metal interconnect with the metal brazing material.

18. The susceptor according to claim 17, wherein the metal brazing material is an alloy comprising at least five metals selected from the group consisting of: aluminum, chromium, molybdenum, titanium, tantalum, gold, lead, and platinum.

19. The susceptor according to claim 17, wherein the first metal interconnect is formed from molybdenum doped with lanthanum oxide, wherein the lanthanum oxide has a concentration of 0.1 to 0.7 atomic %.

20. The susceptor according to claim 17, wherein the susceptor further comprises:
a plurality of electrodes embedded within the heater and electrically connected to the first metal interconnect, wherein the plurality of electrodes are configured to generate an electric charge at the first surface of the heater.
